(19) United States
(12) Patent Application Publication
(10) Pub. No.: US 2015/0309132 A1
(43) Pub. Date: Oct. 29, 2015

(54) APPARATUS, METHOD AND COIL ARRAY FOR PROVIDING SPLIT PARALLEL TRANSMISSION MAGNETIC RESONANCE IMAGING

(71) Applicant: NEW YORK UNIVERSITY, New York, NY (US)

(72) Inventors: RYAN BROWN, New York, NY (US); MARTIJN CLOOS, New York, NY (US); GRAHAM WIGGINS, New York, NY (US)

(73) Assignee: NEW YORK UNIVERSITY

(21) Appl. No.: 14/695,985

(22) Filed: Apr. 24, 2015

Related U.S. Application Data
(60) Provisional application No. 61/983,774, filed on Apr. 24, 2014.
(60) Provisional application No. 61/983,933, filed on Apr. 24, 2014.

(51) Int. Cl. G01R 33/34; G01R 33/483; G01R 33/561; G01R 33/36

(52) U.S. Cl. CPC G01R 33/34084; G01R 33/34092; G01R 33/3614; G01R 33/4833; G01R 33/5612

(57) ABSTRACT

An exemplary coil arrangement can be provided that can include a lateral coil array(s) configured to transmit a set of tailored pulses, and a contralateral coil array(s) configured to transmit the pulses. The lateral coil array(s) and the contralateral coil(s) array can be substantially identical. The pulses can include a set of radio frequency tailored pulses. The lateral coil array(s) and the contralateral coil array(s) can be further configured to transmit a radio frequency shim. A radio frequency shield can be included which can he associated with one of the arrays, and can be located between medial coils. The set of tailored pulses can be parallel pulses. The coil arrangement can be configured to be used at at least about 7 Tesla. The lateral coil array(s) can include at least 2 lateral coils. The contralateral coil array(s) can include at least 2 contralateral coils.

### CROSS-REFERENCE TO RELATED APPLICATION(S)

This application relates to and claims priority from U.S. Patent Application No. 61/983,774, filed on Apr. 24, 2014, and U.S. Patent Application No. 61/983,933, filed on Apr. 24, 2014, the entire disclosures of which are incorporated herein by reference.

### FIELD OF THE DISCLOSURE

The present disclosure relates generally to magnetic resonance imaging “MRI”), and more specifically, to exemplary embodiments of an exemplary expandable parallel transmission MRI system, apparatus, computer-accessible medium and array, and methods for using the same.

### BACKGROUND INFORMATION

MRI of tissue (e.g., breast tissue) can be appealing because of the opportunity for lesion conspicuity, sub-millimeter spatial resolution, and the ability to discern spectral information. However, a MRI transmit system can be challenging to design because of the conflicting requirements of a uniform transmit field and a large field-of-view (“FOV”) required to image the human body (e.g. the breast or the torso). Parallel transmission (“pTx”) can be utilized to homogenize the transmit field, as well as to enable new quantitative techniques such as parallel transmit fingerprinting (see e.g., Reference 11); however, the application of pTx imaging may not be straightforward because most pix systems may only provide eight or fewer transmit channels.

Thus, it may be beneficial to provide an exemplary system, method, and computer-accessible medium in which a given radio frequency (“RF”) shim or set of tailored pulses can be replicated across identical lateral and contralateral coil arrays to effectively double the field-of-view without compromising performance, and which can overcome at least some of the deficiencies described herein above.

### SUMMARY OF EXEMPLARY EMBODIMENTS

An exemplary coil arrangement can be provided that can include, for example, a lateral coil array(s) configured to transmit a first set of pulses, and a contralateral coil array(s) configured to transmit a second set of pulses, where the first and second sets of pulses have substantially the same characteristics. The lateral coil array(s) and the contralateral coil(s) array can be substantially identical. The first and second sets of pulses can include a set of radio frequency tailored pulses. The lateral coil array(s) and the contralateral coil array(s) can be further configured to transmit a radio frequency shim (e.g., a pulse with a different magnitude phase at each coil element). A radio frequency shield can be included which can be associated with one of the arrays, and can be located between medial coils. The first and second sets of pulses can be parallel pulses.

In some exemplary embodiments of the present disclosure, the exemplary coil arrangement can be configured to be used at at least about 7 Tesla. The lateral coil array(s) can include at least 2 lateral coils or modes, which can be arranged on a cylindrical former having azimuthal symmetries. The contralateral coil array(s) can include at least 2 contralateral coils, which can be arranged on a cylindrical former haying azimuthal symmetries, or the contralateral coil array(s) can include at least two modes. The lateral coil array(s) or the contralateral coil array(s) can be configured to drive a particular transmit mode, which can be a circularly polarized mode or an anti-circular polarized mode. The first and second sets of pulses can be sets of tailored pulses. The sets of tailored pulses can be based on as superposition of electromagnetic field that can be caused by a further coil arrangement having an excitation or an electrical field pattern that can overlap with the coil arrangement.

In certain exemplary embodiments of the present disclosure a power splitter(s) can be configured to provide an initial set of pulses to the lateral coil array(s) and the contralateral coil array(s). The power splitter(s) can be a radio frequency power splitter(s). The first and second sets of pulses can be a sets of identical radio frequency pulses. In some exemplary embodiments of the present disclosure, each of the coil array(s) and the contralateral coil array(s) can include (i) a plurality of transmit/receive switches, (ii) a power divider coupled to the transmit/receive switches, and/or (iii) at least two coils coupled to the power divider. An image(s) of an anatomical structure(s) can be generated based on the first and second sets of pulses.

Another exemplary embodiment of the present disclosure can include a method for utilizing a coil configuration, which can include, for example transmitting a first set of pulses using a lateral coil array(s), and transmitting a second set of pulses using a contralateral coil array(s), wherein the first and second sets of pulses have substantially the same characteristics.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1A is an exemplary schematic diagram of the exemplary split-symmetric coil according to an exemplary embodiment of the present disclosure:

FIG. 1B is a schematic of traditionally-driven transmit coils;

FIG. 1C is an exemplary diagram of the exemplary split-symmetric coil of FIG. 1A according to an exemplary embodiment of the present disclosure;

FIG. 2 is a set of images acquired using individual transmitters illustrating the symmetric nature of the exemplary paired coil's field distributions according to an exemplary embodiment of the present disclosure;

FIGS. 3A and 3B are images illustrating improved coverage in the posterior breast according to an exemplary embodiment of the present disclosure;

FIGS. 4A and 4B are images illustrating uniform T_{2w} Turbo Spin Echo sequence according to an exemplary embodiment of the present disclosure;

FIG. 5A is a diagram of an exemplary bilateral coil according to an exemplary embodiment of the present disclosure;

FIG. 5B is a diagram of an exemplary coil used for a body, a head or a knee according to an exemplary embodiment of the present disclosure;

FIG. 5C is a diagram of an exemplary helmet coil according to an exemplary embodiment of the present disclosure;

FIG. 6 is an exemplary flow chart of a method for transmitting sets of pulses according to an exemplary embodiment of the present disclosure; and

FIG. 7 is an illustration of an exemplary block diagram of an exemplary system in accordance with certain exemplary embodiments of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

The performance of various exemplary parallel transmit MRI methodologies can improve with the number of transmit channels available. Each transmit channel can typically be used to drive a single transmit coil, thereby producing a spatially localized excitation pattern. This pattern can be tailored in a desirable fashion through temporal variations of the excitation pulse, or through the superposition of electromagnetic fields by introducing a second coil whose excitation (e.g. magnetic field) and/or electrical field pattern can overlap with that of the first coil. Thus, the number of transmit channels can be proportional to the upper limit of the degrees of freedom over which an associated optimization problem (e.g. RF shimming, tailored pulse design or MR fingerprinting), etc. can be solved. If a multitude of coils can be driven with a single transmit channel, the geometrical size of coil elements utilized to cover a given surface can be reduced, which can result in a greater level of spatial localization provided by an individual coil, and can enhance the ability to tailor the magnetic and electric fields compared to a traditionally-driven transmit coil array.

The exemplary system, apparatus, and method according to an exemplary embodiment of the present disclosure, can increase the degrees of freedom in an exemplary parallel transmit system by the introduction of an exemplary mechanism (e.g., a power splitter or quadrature hybrid), that can be used to facilitate multiple coils to be driven through a single transmit channel. As a result, e.g., the number of transmit coils can be multiplicatively increased (e.g. by the power splitter ratio), which can facilitate a reduction in the geometrical size of the coil elements used to cover a given surface. This can result in a greater level of spatial localization provided by an individual coil in the array, which can lead to the desirable effects described above, as well as reduced local electric fields as compared to a traditionally-driven transmit coil array. The exemplary split transmission system, apparatus and method, according to an exemplary embodiment of the present disclosure, can differ from other transmit procedures techniques (e.g., driving a transmit array through a Butler matrix (see e.g., Reference 12) or singular value decomposition (“SVD”) hardware (see e.g., Reference 13). For example, the exemplary system, apparatus and method according, to exemplary embodiments of the present disclosure can split individual transmit channels to drive a particular mode (e.g. circularly polarized mode or anti-circular polarized mode) by exciting multiple coil elements with pre-defined phase relations. The exemplary system, apparatus and method can also be applied to drive an arbitrary subset of coils within the exemplary array. Thus, the exemplary system, apparatus and method can offer more freedom to tailor both the geometrical structure of the array and the driving configuration.

The exemplary system, apparatus and method, according to an exemplary embodiment of the present disclosure, which can drive multiple coils with a single transmission channel, can be applied to an array that can include an arbitrary number of coils in an arbitrary geometric arrangement. For performance (e.g., optimal performance), factors inherent in the coil geometry and targeted anatomical region can be exploited. For example, transmit coil arrays for head, knee or body imaging can be arranged on a cylindrical former with azimuthal symmetries. In such an exemplary case, coils driven through a common transmit channel can share approximately the same azimuthal position. For a coil array arranged on an arbitrary surface (e.g. dome or helmet for head imaging), the exemplary system, apparatus and method can be configured such that the relative phase difference between neighboring coils (e.g. those that do not share the same transmit channel) can be respected according to approximate geometrical relations relative to, (e.g., the center of the imaged object). An example of this can be a bilateral breast imaging system, which can utilize the exemplary system, apparatus and method, and associated coil array, to exploit the body's left-right symmetry.

### Exemplary Method and System

The exemplary system, apparatus and method, according to an exemplary embodiment of the present disclosure, can exploit geometrical symmetries in the body and the coil array. Thus, the exemplary system, apparatus and method can include on or more lateral coil arrays including one or more coils, and one or more lateral coil arrays also including one or more coils. In the exemplary case of bilateral breast imaging, symmetries in the body and coil can be exploited by driving a pair of coils (e.g. the lateral and contralateral coils) that can share approximately the same azimuthal location with respect to the center of the lateral and contralateral breast. Identical, or substantially identical, lateral and contralateral breast arrays can experience similar loading conditions, can have a low level of interaction (e.g., independent and separate FOVs), and can generate similar field distributions. This exemplary framework can substantially increase the degrees of freedom associated with the bilateral transmit optimization problem.

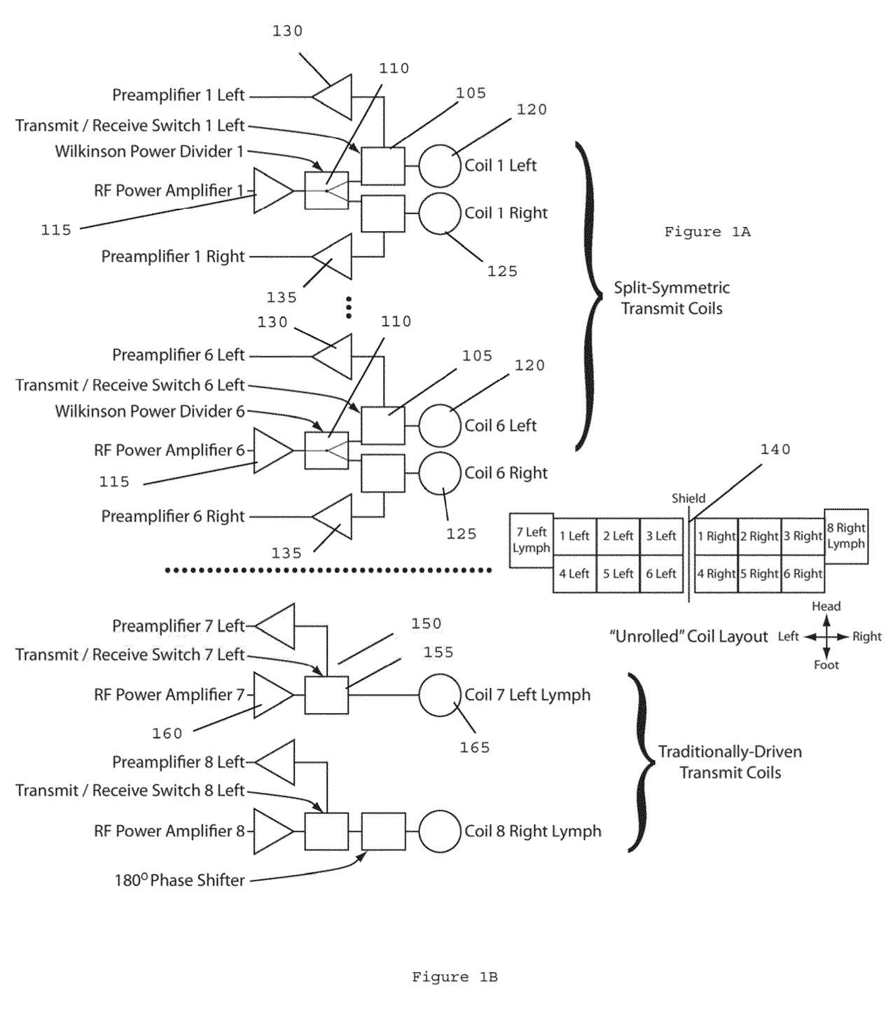

FIG. 1A illustrates an exemplary system, apparatus, arrangement (e.g., split-symmetric pTx system) and method, according to an exemplary embodiment of the present disclosure. As shown in FIG. 1A, the exemplary system, method and computer-accessible medium can drive a set of transmit/receive switches, for example about 14 transmit/receive switches (e.g., switches 105), and can drive power dividers, such as Wilkinson power dividers, (e.g., dividers 110) with independent RF amplifiers 115 (e.g., a preamplifier). For example, each of the outputs of the Wilkinson power dividers 110 can be fed to paired coils 120 and 125 (e.g., paired breast coils) within the lateral and contralateral arrays. (See e.g., FIG. 1C). The two remaining amplifiers (e.g., amplifiers 130 and 135) can independently drive lymph node coils (e.g., or about 6×7 cm²). The exemplary breast coils/arrays can include six 8×8 cm² coils arranged in a 2×3 grid covering about a 1.5 L aperture. A passive RF shield 140 can be inserted between the medial coils to reduce coupling to less than about −12 dB, while reactive decoupling can reduce interaction between adjacent coils to less than about −12 dB. Signal reception can be performed by feeding signals from each coil through independent transmit/receive switches 105 and preamplifiers 115. Imaging can be performed on a whole-body 7T scanner equipped with an eight-channel pTx system (e.g., MAGETOM, Siemens).

FIG. 1B illustrates a schematic diagram of traditionally-driven transmit coils 150. As shown in FIG. 1B, each traditionally-driven transmit coil can include a RF power amplifier 155 coupled to a transmit/receive switch 160, which can drive coil 165. Traditionally-driven transmit coils 150, however, may not include Wilkinson power divider 110, preamplifier 135, and do not drive a pair of breast coils (e.g., breast coils 120 and 125).

### Exemplary Results

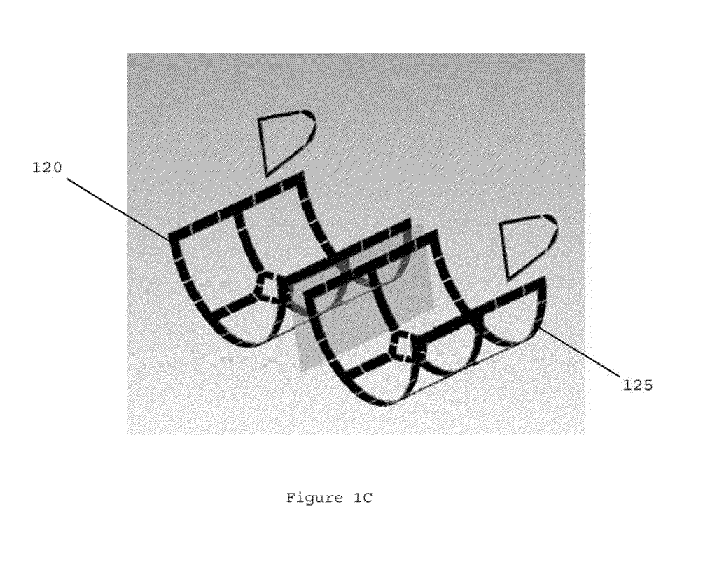

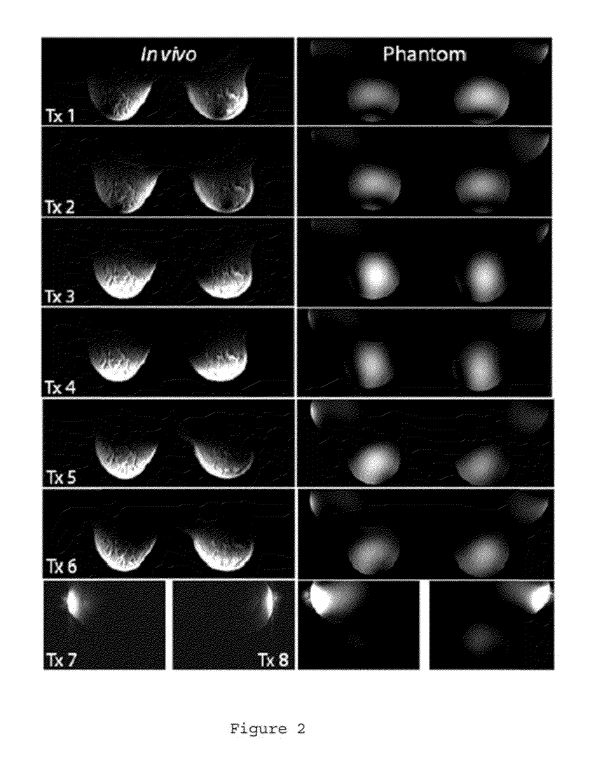

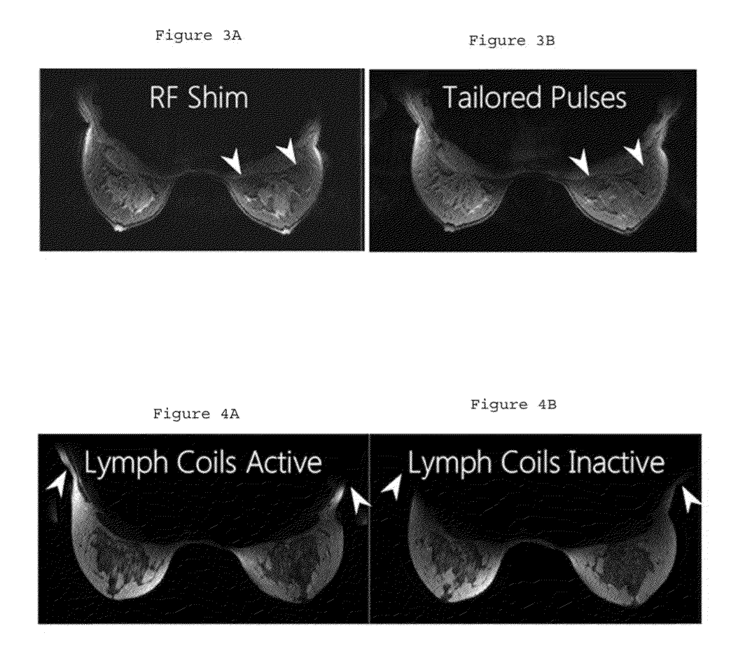

The symmetric nature of the transmit fields generated by the exemplary paired coil elements is illustrated in the set of images of FIG. 2. While the individual transmitters shown in FIG. 1A appear to have low depth penetration, a straightforward phase-coherent RF shim a pulse with a different magnitude phase at each coil element) can provide excellent uniformity throughout the volume, as can be seen in the T1w 3D spoiled Gradient Echo (“GRE”) images. (See e.g., FIG. 3A). Coverage can be further improved using tailored parallel pulses, particularly in the posterior breast. (See e.g., FIG. 3B). Transmit uniformity can again be highlighted in T2w Turbo Spin Echo (“TSE”) images, a sequence that has been difficult to perform in the breast at 7T. (See e.g., FIG. 4.) Acquisitions with and without the lymph node coils reveal the associated coverage expansion. (See e.g., FIG. 4B).

### Exemplary Embodiments

The exemplary system apparatus and method can be used to utilize body and coil symmetries to double the coverage, without reducing the degrees of freedom associated with the transmit optimization problem. These additional degrees of freedom can be translated into a lower local specific absorption rate, or improved coverage with tailored transmit pulses, which can be beneficial in the posterior breast and axillary tail, regions that have been difficult to access with standard single channel transmit coils. In a similar manner, the exemplary split-symmetric coil halved the channel count on each breast, facilitating dedicated lymph node coils to be allocated for additional coverage. Independent control of the lymph node coils permitted, for example, local FOV imaging (e.g., with the coils enabled) or standard bilateral breast imaging (e.g., with the coils disabled). Second generation lymph node coils can be further optimized to satisfy tradeoffs between patient comfort and coverage. While the lymph node coils facilitated flexible positioning, fixed coils embedded in the main coil housing can be advantageous for patient comfort.

Exemplary coils 1 to 6 of the exemplary system and apparatus were paired in a translational manner (e.g., left/lateral and right/medial coils were paired). (See e.g., see FIG. 1C). This can be advantageous due to the symmetry in their transmit field patterns. One disadvantage can be dissimilar loading; the lateral coils can be adjacent to the arms and shoulders, whereas the medial coils may not be. Pairing coils in a mirrored manner in which the left/lateral coil can be paired with the right/lateral coil can alleviate this issue. However, while a mirrored configuration can suffer from opposed “B1+twisting”, compromising the underlying framework of the split symmetric transmit scheme, an exemplary mirror-paired configuration can be trivially implemented with the exemplary system/apparatus by properly pairing the Wilkinson outputs and adding a 180° phase shift to the contralateral transmit path.

While the exemplary split symmetric system can be used at high field or ultra-high field (e.g., >=7T), the system can also be applicable to breast imaging at other or clinical field strengths (e.g., 1T or 3T). The exemplary system/apparatus can address the transmit heterogeneity issues observed in the 3T and 1.5T breast imaging community. (See e.g., References 7-10). By improving the transmit uniformity, the exemplary system/apparatus can improve fat suppression, and any quantitative procedures that rely on a uniform transmit field (e.g., enhancement ratio (see e.g., Reference 7) and T1 mapping (see e.g. Reference 8)).

Another advantage of the exemplary split-symmetric transmit system applied to clinical breast imaging at 1.5 and 3T can be a reduction in global SAR. This exemplary benefit can stem from the use of local transmit coils rather than the traditional fully-encompassing body coil that inefficiently deposits a large amount of energy into the torso and arms during breast MRI. Thus, the exemplary system can facilitate faster and more exotic acquisition procedures.

The exemplary split symmetric system can be expandable to any suitable number of available transmit channels or coils. In one example, multiplexing 2 to 6 transmit channels to drive 4 to 12 coils can be sufficient for breast imaging at 1.5 or 3T.

The exemplary split-symmetric system demonstrated a way to utilize symmetries in the body anatomy by bilaterally replicating both the transmit array and associated transmit pulses. This exemplary system can provide a good B1+uniformity, and enables improved coverage in the posterior breast with tailored pulses and in the lymph nodes with dedicated coils. Further, combined transmit/receive arrays can be beneficial in breast imaging where spatial limitations make separate transmit and receive arrays difficult to package. The exemplary pTx system can also improve transmit-sensitive protocols such as T2w TSE and saturation-based fat suppression, provide improved coverage in the posterior breast and facilitate the ability to locally excite the lymph nodes with independently controllable coils.

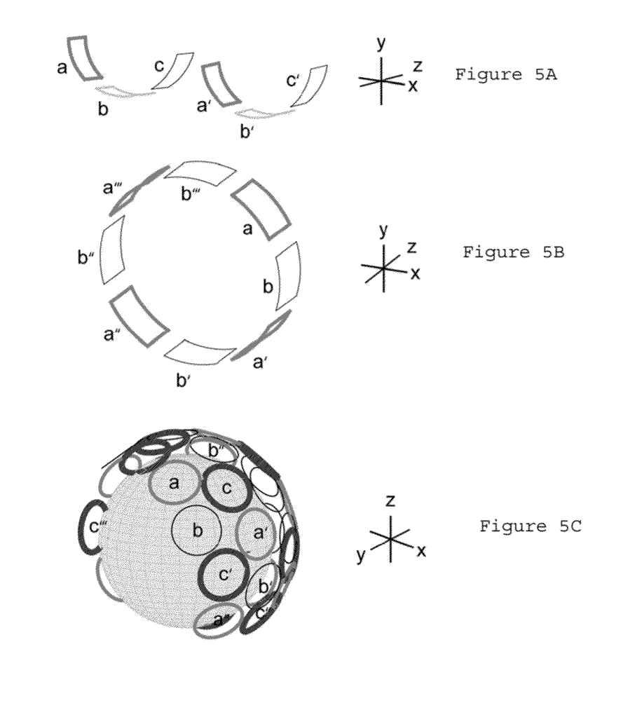

FIGS. 5A-5C illustrate exemplary coil geometries for the exemplary split symmetric system. As shown in FIGS. 5A-5C, multiple coils can be driven using a single transmit line, or amplifier, to provide more degrees of freedom than in a standard pTx configuration. Paired coils (e.g., those being driven from the same amplifier) can be selected, for example, in a strict lateral/contralateral arrangement. (See e.g., FIG. 5A). This exemplary arrangement can be used in the exemplary array for bilateral breast imaging. Paired coils can be selected from a particular subset of the array that can be arranged to drive a particular mode (e.g., circularly polarized, anti-circularly polarized, linear, gradient, Helmholtz, etc.). (See e.g., FIG. 5B) The exemplary coil arrangement illustrated in FIG. 5B can be used, for example, to image the whole-body, the head or the knee. Paired coils can also be arranged on an arbitrary surface (see e.g., FIG. 5C), in order to drive a particular mode (e.g., circularly polarized, anti-circularly polarized, linear, gradient, Helmholtz, etc.), or to highlight a particular spatial location. This exemplary coil arrangement can be used, for example, to image the head (e.g., tight-fitting helmet arrays) or other arbitrary geometries. Each coil a, a′, a″, b, b′ and b′″, and c′, c′ and c′″ can be driven by the same amplifier. Each coil can have a specific phase and/or amplitude offset in order to optimize a particular configuration. However, in certain exemplary situations, optimization may not be needed.

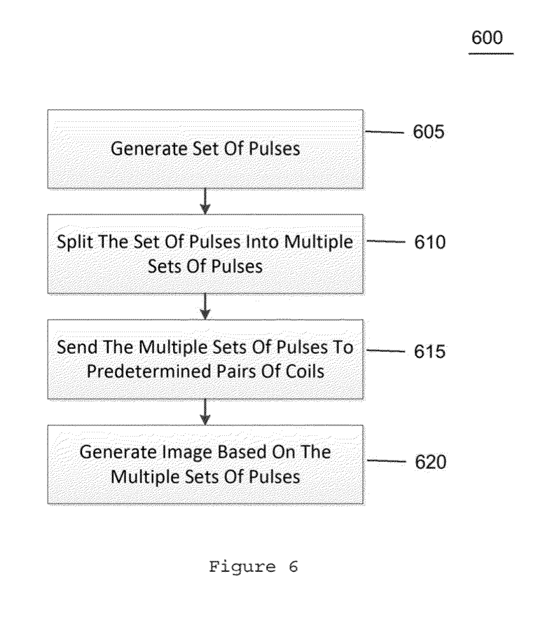

FIG. 6 is an exemplary flow chart of a method 600 for generating an image. For example, at procedure 605, a set of pulses can be generated. At procedure 610, the pulses can be split into multiple sets of pulses. At procedure 615, the multiple sets of pulses can be sent to pairs of physical coils or pairs of coil modes, and an image can be generated based on the multiple sets of pulses at procedure 620.

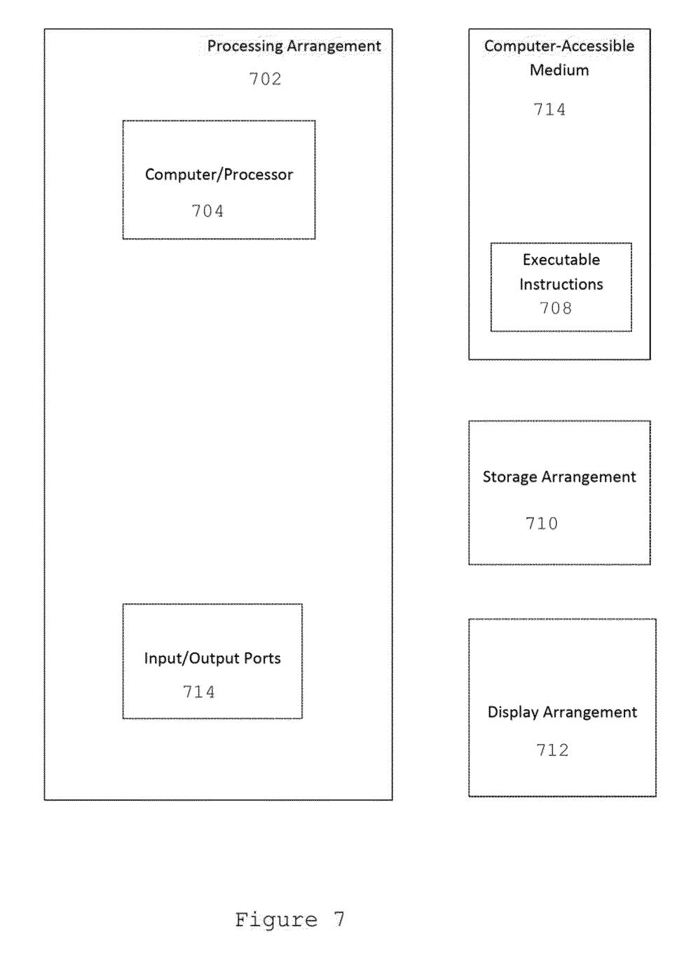

FIG. 7 shows a block diagram of an exemplary embodiment of a system according to the present disclosure. For example, exemplary procedures in accordance with the present disclosure described herein can be performed by a processing arrangement and/or a computing arrangement 702. Such processing/computing arrangement 702 can be, for example entirely or a part of, or include, but not limited to, a computer/processor 704 that can include, for example one or more microprocessors, and use instructions stored on a computer-accessible medium (e.g., RAM, ROM, hard drive, or other storage device).

As shown in FIG. 7, for example a computer-accessible medium 706 (e.g., as described herein above, a storage device such as a hard disk, floppy disk, memory stick, CD-ROM, RAM, ROM, etc., or a collection thereof) can be provided (e.g., in communication with the processing arrangement 702). The computer-accessible medium 706 can contain executable instructions 708 thereon. In addition or alternatively, a storage arrangement 710 can be provided separately from the computer-accessible medium 706, which can provide the instructions to the processing arrangement 702 so as to configure the processing arrangement to execute certain exemplary procedures, processes and methods, as described herein above, for example.

Further, the exemplary processing arrangement 702 can be provided with or include an input/output arrangement 714, which can include, for example a wired network, a wireless network, the internet, an intranet, a data collection probe, a sensor, etc. As shown in FIG. 7, the exemplary processing arrangement 702 can be in communication with an exemplary display arrangement 712, which, according to certain exemplary embodiments of the present disclosure, can be a touch-screen configured for inputting information to the processing arrangement in addition to outputting information from the processing arrangement, for example. Further, the exemplary display 712 and/or a storage arrangement 710 can be used to display and/or store data in a user-accessible format and/or user-readable format.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

### EXEMPLARY REFERENCES

The following references are hereby incorporated by reference in their entirety.

1. Brown R, Storey P. Geppert C, McCarty K. Klautau Leite A P, Babb J, Sodickson D K, Wiggins G C, Moy L. Breast MRI at 7 Tesla with a bilateral coil and robust fat suppression. J Magn Reson Imaging 2014;39(3):540-549.

2. Brown R, Storey P, Geppert C, McGorty K, Leite A P, Babb J, Sodickson D K, Wiggins G C, Moy L. Breast MRI at 7 Tesla with a bilateral coil and T1-weighted acquisition with robust fat suppression: image evaluation and comparison with 3 Tesla. Eur Radiol 2013;23(11):2969-2978.

3. Korteweg M A, Veldhuis W B, Visser F, Luijten P R, Mali W P, van Diest P J, van den Bosch M A, Klomp D J. Feasibility of 7 Tesla breast magnetic resonance imaging determination of intrinsic sensitivity and high-resolution magnetic resonance imaging, diffusion-weighted imaging, and (1)H-magnetic resonance spectroscopy of breast cancer patients receiving neoadjuvant therapy. Invest Radial 2011;46(6):370-376.

4. Umutlu L, Maderwald S. Kraff O, Theysohn J M, Kuemmel S, Hauth E A, Forsting M, Antoch G, Ladd M E, Quick H H, Lauenstein T C. Dynamic contrast-enhanced breast MRI at 7 Tesla utilizing a single-loop coil: a feasibility trial. Acad Radial 2010;17(8):1050-1056.

5. Zaric O, Pinker K, Gruber S. Porter D, Helbich T. Trattnig S. Bogner W. Diffusion Weighted Imaging of the Breast at 7T—Ready for Clinical Application?. ISMRM. Salt Lake City, Utah; 2013. p 196.

6. van de Bank B L, Voogt I J, Italiaander M, Stehouwer B L, Boer V O, Luijten P R, Klomp D W J. Ultra high spatial and temporal resolution breast imaging at 7T. NMR Biomed 2013;26:367-375.

7. Azlan C A, Di Giovanni P, Ahearn T S, Semple S I, Gilbert F J, Redpath T W. B1 transmission-field inhomogeneity and enhancement ratio errors in dynamic contrast-enhanced MRI (DCE-MRI) of the breast at 3T. J Magn Reson Imaging 2010;31(1)1234-239.

8. Sung K. Daniel B L, Hargreaves B A. Transmit B1+field inhomogeneity and T1 estimation errors in breast DCE-MRI at 3 tesla. J Magn Reson Imaging 2013;38(2):454-459.

9. Kuhl C K, Kooijman H. Gieseke J, Schikl H H. Effect of B1 inhomogeneity on breast MR imaging at 3.0 T. Radiology 2007;244(3):929-930.

10. Hancu I. Lee S K, Dixon W T, Sacolick L. Becerra R, Zhang Z, McKinnon G, Alagappan V. Field shaping arrays: a means to address shading in high field breast MRI. J Magn Reson Imaging 2012;36(4):865-872.

11. Cloos et al., “Plug and Play Parallel Transmission at 7 and 9.4 Tesla based on Principles from MR Fingerprinting,” ISMRM 2014.

12. Alagappan, et al. “A Simplified 16-channel Butler Matrix for Parallel Excitation with the Birdcage Modes at 7T.” Proc ISMRM 2008. P 144.

13. Ferrand, et al. “SVD-based Hardware Concept to Drive N Transmit Elements of a Phased Array Coil with channels for High Field MRI.” Proc ISMRM 2011. P 3888.

What is claimed is:

1. A coil arrangement, comprising:
at least one lateral coil array configured to transmit a first set of pulses; and
at least one contralateral cod array configured to transmit a second set of pulses, wherein the first and second sets of pulses have substantially the same characteristics.

2. The coil arrangement of claim 1 wherein the at least one lateral coil array and the at least one contralateral coil array are substantially identical.

3. The coil arrangement of claim 1, wherein the first and second. sets of pulses include a set of radio frequency (RF) pulses.

4. The coil arrangement of claim 3, wherein the at least one lateral coil array and the at least one contralateral coil array are further configured to transmit a radio frequency shim.

5. The coil arrangement of claim 1, further comprising at least one radio frequency shield associated with at least one of the arrays, and located between medial coils.

6. The coil arrangement of claim 1, wherein the first and second sets of pulses are parallel pulses.

7. The coil arrangement of claim 1, wherein the coil arrangement is configured to be used at at least about 7 Tesla.

8. The coil arrangement of c arm wherein the at least one lateral coil array includes at least two lateral coils.

9. The coil arrangement of claim 8, wherein the at least two coils are arranged on a cylindrical former having azimuthal symmetries.

10. The coil arrangement of claim 1, wherein the at least one contralateral coil array includes at least two contralateral coils.

11. The coil arrangement of claim 10, wherein the at least two contralateral coils are arranged on a cylindrical former having azimuthal symmetries.

12. The coil arrangement of claim 1, wherein at least one of the at least one lateral coil array or the at least one contralateral coil array is configured to drive a particular transmit mode.

13. The coil arrangement of claim 12, wherein the at least one transmit mode is at least one of a circularly polarized mode or an anti-circular polarized mode.

14. The coil arrangement of claim 1, wherein the first and second sets of pulses are sets of tailored pulses.

15. The coil arrangement of claim 14, wherein the sets of tailored pulses are based on a superposition of electromagnetic fields (EM).

16. The coil arrangement of claim 14, wherein the superposition of EM fields is caused by a further coil arrangement having at least one of an excitation or an electrical field pattern that overlaps with the coil arrangement.

17. The coil arrangement of claim 1, further comprising at least one power splitter configured to provide at least one initial set of pulses to the at least one lateral coil array and the at least one contralateral coil array.

18. The coil arrangement of claim 17, wherein the at least one power splitter is at least one radio frequency power splitter.

19. The coil arrangement of claim 18, wherein the first and second sets of pulses is a set of identical radio frequency pulses.

20. The coil arrangement of claim 1, wherein each of the at least one lateral coil array and the at least one contralateral coil array includes:
a plurality of transmit/receive switches,
a power divider coupled to the transmit/receive switches, and
at least two coils coupled to the power divider.

21. The coil arrangement of claim 1, further comprising a computer arrangement which is configured to generate at least one image of at least one anatomical structure based on the first and second sets of the pulse.

22. A method for utilizing a coil configuration, comprising:
transmitting as first set of pulses using at least one lateral coil array; and
transmitting a second set of pulses using, at least one contralateral coil array, wherein the first and second sets of pulses have substantially the same characteristics.
